(19) United States
(12) Patent Application Publication
(10) Pub. No.: US 2022/0085199 A1
(43) Pub. Date: Mar. 17, 2022

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Chisato FURUKAWA, Komatsu Ishikawa (JP)

(21) Appl. No.: 17/472,453

(22) Filed: Sep. 10, 2021

(30) Foreign Application Priority Data
Sep. 16, 2020 (JP) 2020-155894

(51) Int. Cl. H01L 29/778; H01L 29/20; H01L 29/40

(52) U.S. Cl. CPC H01L 29/7786; H01L 29/407; H01L 29/2003

(57) ABSTRACT

A semiconductor device includes: a first nitride semiconductor layer having a first surface and a second surface facing the first surface; a first source electrode provided below the first surface; a first drain electrode provided below the first surface; a first gate electrode provided below the first surface and the first gate electrode being provided between the first source electrode and the first drain electrode; a second nitride semiconductor layer provided on the second surface, the second nitride semiconductor layer having a third surface in contact with the second surface and a fourth surface facing the third surface and the second nitride semiconductor layer having a smaller band gap than the first nitride semiconductor layer; a first silicon substrate provided on the fourth surface and the first silicon substrate having a fifth surface in contact with the fourth surface and a sixth surface facing the fifth surface; a second silicon substrate provided on the sixth surface and the second silicon substrate having a seventh surface bonded with the sixth surface and an eighth surface facing the seventh surface; a first semiconductor layer of first conductivity type provided on the second silicon substrate or in the second silicon substrate; a second semiconductor layer of first conductivity type provided on the first semiconductor layer and the second semiconductor layer having a lower concentration of impurities of first conductivity type than the first semiconductor layer; a first semiconductor region of second conductivity type provided on the second semiconductor layer; a second semiconductor region of first conductivity type provided on the first semiconductor region; a second gate electrode provided above the first semiconductor layer, the second gate electrode facing the first semiconductor region with a gate insulating film interposed between the second gate electrode and the first semiconductor region; and a second source electrode provided on the second semiconductor region and the second source electrode being electrically connected to the second semiconductor region.

### CROSS-REFERENCE TO RELATED APPLICATION

This application is based upon and claims the benefit of priority from Japanese Patent Application No. 2020-155894, filed on Sep. 16, 2020, the entire contents of which are incorporated herein by reference.

### FIELD

Embodiments described herein relate generally to a semiconductor device.

### BACKGROUND

Group III nitrides, for example, gallium nitride (GaN)-based semiconductors are expected as materials for next-generation power semiconductor devices. GaN-based semiconductors have a large band gap as compared with silicon (Si). Therefore, a GaN-based semiconductor device can realize a power semiconductor device that is smaller and has a higher breakdown voltage than a silicon (Si) semiconductor device. In addition, since the parasitic capacitance can be reduced in this manner, a high-speed drive power semiconductor device can be realized.

In GaN-based transistors, a high electron mobility transistor (HEMT) structure using a two-dimensional electron gas (2DEG) as a carrier is generally applied. A GaN-based HEMT is a normally-on transistor through which a current flows even if no voltage is applied to the gate. For this reason, there is a problem that it is difficult to realize a normally-off transistor through which no current flows unless a voltage is applied to the gate.

In a power supply circuit or the like for handling a large amount of electric power of several hundred V to 1000 V, a normally-off operation is required with an emphasis on safety. Therefore, a circuit configuration has been proposed in which a normally-on GaN-based transistor and a normally-off Si transistor are cascode-connected to realize a normally-off operation.

### BRIEF DESCRIPTION OF THE DRAWINGS

FIG. 1 is a schematic cross-sectional view of a semiconductor device of a first embodiment;

FIG. 2 is a schematic cross-sectional view of a semiconductor device of the first embodiment;

FIG. 3 is a schematic cross-sectional view of the semiconductor device of the first embodiment;

FIG. 4 is a circuit diagram of the semiconductor device of the first embodiment;

FIG. 5 is a schematic cross-sectional view of a semiconductor device of a second embodiment; and

FIG. 6 is a circuit diagram of the semiconductor device of the second embodiment.

### DETAILED DESCRIPTION

Hereinafter, embodiments will be described with reference to the diagrams. In the following description, the same members and the like are denoted by the same reference numerals, and the description of the members and the like once described will be omitted as appropriate.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

Hereinafter, a case where the first conductivity type is n type and the second conductivity type is p type will be described as an example.

In the following description, when there are notations of n⁺, n, n⁻, p⁺, p, and p⁻, these indicate the relative high and low of the impurity concentration in each conductivity type. That is, n⁺ indicates that the n-type impurity concentration is relatively higher than n, and n-indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

### First Embodiment

A semiconductor device of the present embodiment includes: a first nitride semiconductor layer having a first surface and a second surface facing the first surface; a first source electrode provided below the first surface; a first drain electrode provided below the first surface; a first gate electrode provided below the first surface and the first gate electrode being provided between the first source electrode and the first drain electrode; a second nitride semiconductor layer provided on the second surface, the second nitride semiconductor layer having a third surface in contact with the second surface and a fourth surface facing the third surface and the second nitride semiconductor layer having a smaller band gap than the first nitride semiconductor layer; a first silicon substrate provided on the fourth surface and the first silicon substrate having a fifth surface in contact with the fourth surface and a sixth surface facing the fifth surface; a second silicon substrate provided on the sixth surface and the second silicon substrate having a seventh surface bonded with the sixth surface and an eighth surface facing the seventh surface; a first semiconductor layer of first conductivity type provided on the second silicon substrate or in the second silicon substrate; a second semiconductor layer of first conductivity type provided on the first semiconductor layer and the second semiconductor layer having a lower concentration of impurities of first conductivity type than the first semiconductor layer; a first semiconductor region of second conductivity type provided on the second semiconductor layer; a second semiconductor region of first conductivity type provided on the first semiconductor region; a second gate electrode provided above the first semiconductor layer, the second gate electrode facing the first semiconductor region with a gate insulating film interposed between the second gate electrode and the first semiconductor region; and a second source electrode provided on the second semiconductor region and the second source electrode being electrically connected to the second semiconductor region.

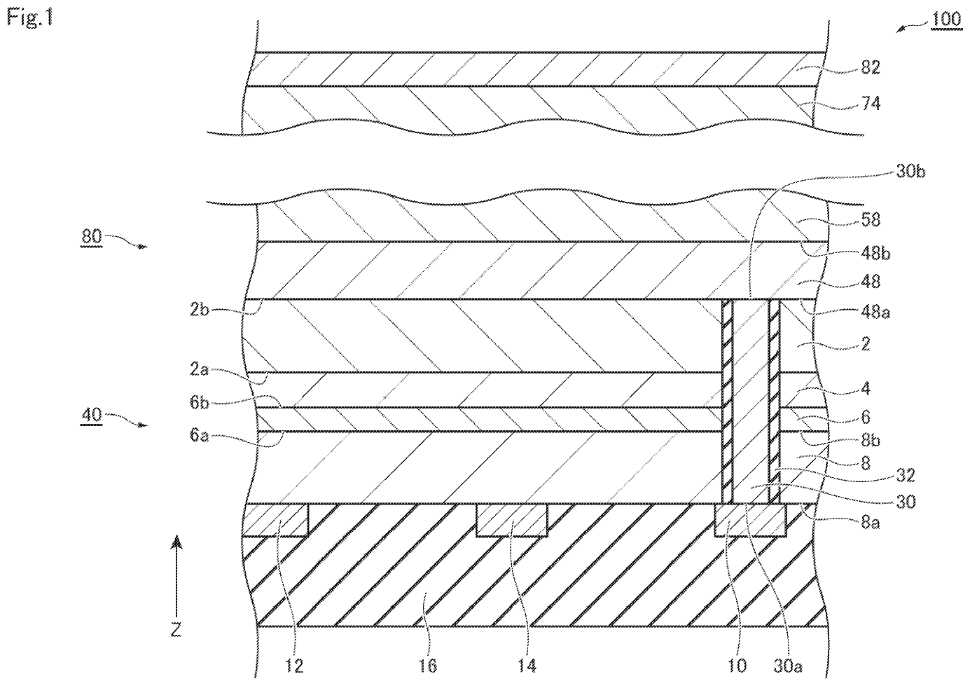

FIG. 1 is a schematic cross-sectional view of a semiconductor device 100 of the present embodiment.

The semiconductor device 100 of the present embodiment is a device in which a nitride semiconductor device 40 and a semiconductor device 80 are electrically connected in series to each other.

The nitride semiconductor device 40 is, for example, a high electron mobility transistor (HEMT).

The nitride semiconductor device 40 includes a first silicon substrate 2, a third nitride semiconductor layer 4, a second nitride semiconductor layer 6, a first nitride semiconductor layer 8, a first source electrode 10, a first drain electrode 12, a first gate electrode 14, an interlayer insulating film 16, a first through electrode 30, and a first insulating film 32.

The first nitride semiconductor layer 8 has a first surface 8a and a second surface 8b facing the first surface 8a. The first nitride semiconductor layer 8 is disposed so that the first surface 8a faces down. The first nitride semiconductor layer 8 is, for example, undoped Al_{Y}Ga_{1-Y}N (0<Y≤1). More specifically, the first nitride semiconductor layer 8 is, for example, undoped Al_{0.2}Ga_{0.8}N. The thickness of the first nitride semiconductor layer 8 is, for example, 15 nm or more and 50 nm or less.

The second nitride semiconductor layer 6 is provided on the second surface 8b. The second nitride semiconductor layer 6 has a third surface 6a and a fourth surface 6b facing the third surface 6a. The third surface 6a is in contact with the second surface 8b. The band gap of the second nitride semiconductor layer 6 is smaller than the band gap of the first nitride semiconductor layer. The second nitride semiconductor layer 6 is, for example, undoped Al_{X}Ga_{1-X}N (0≤X<1, X<Y). More specifically, the second nitride semiconductor layer 6 is, for example, undoped GaN. The thickness of the second nitride semiconductor layer 6 is, for example, 0.5 μm or more and 3 μm or less.

A heterojunction interface is formed between the first nitride semiconductor layer 8 and the second nitride semiconductor layer 6. A two-dimensional electron gas (2DEG) is generated on the heterojunction interface.

The third nitride semiconductor layer 4 is provided on the fourth surface 6b. The third nitride semiconductor layer 4 functions as a buffer layer for reducing the lattice mismatch with the first silicon substrate 2. The third nitride semiconductor layer 4 is formed in a multilayer structure of aluminum gallium nitride (Al_{W}Ga_{1-W}N (0<W<1)), for example.

The first source electrode 10 is provided below the first surface 8a and is in contact with the first surface 8a. The first drain electrode 12 is provided below the first surface 8a and is in contact with the first surface 8a. The first gate electrode 14 is provided below the first surface 8a, provided between the first source electrode 10 and the first drain electrode 12, and is in contact with the first surface 8a. The first source electrode 10, the first drain electrode 12, and the first gate electrode 14 are, for example, metal electrodes. Each metal electrode used for the first source electrode 10, the first drain electrode 12, and the first gate electrode 14 has, for example, a stacked structure of titanium (Ti) and Al or a stacked structure of nickel (Ni) and gold (Au).

The interlayer insulating film 16 is provided around the first source electrode 10, the first drain electrode 12, and the first gate electrode 14 below the first surface 8a. The interlayer insulating film 16 contains, for example, polyimide or benzocyclobutene (BCB), but is not limited to this.

The first silicon substrate 2 is provided on the third nitride semiconductor layer 4 on the fourth surface 6b. The first silicon substrate 2 has a fifth surface 2a in contact with the fourth surface 6b and a sixth surface 2b facing the fifth surface 2a. When the third nitride semiconductor layer is provided, the fifth surface 2a is in contact with the fourth surface 6b via the third nitride semiconductor layer 4. The first silicon substrate 2 is, for example, a silicon substrate doped with impurities to have electrical conductivity.

The first through electrode 30 penetrates the first nitride semiconductor layer 8, the second nitride semiconductor layer 6, the third nitride semiconductor layer 4, and the first silicon substrate 2. One end 30a of the first through electrode 30 is electrically connected to the first source electrode 10. The other end 30b of the first through electrode 30 is electrically connected to a seventh surface 48a of a second silicon substrate 48. The first through electrode 30 contains, for example, copper (Cu) or aluminum (Al). In addition, the first through electrode 30 may not penetrate the first silicon substrate 2. For example, the other end 30b of the first through electrode 30 may be electrically connected to the fifth surface 2a of the first silicon substrate 2.

The first insulating film 32 is provided around the first through electrode 30. The first insulating film 32 insulates the first nitride semiconductor layer 8, the second nitride semiconductor layer 6, and the third nitride semiconductor layer 4 from the first through electrode 30, for example. The first insulating film 32 contains an insulating material, such as silicon oxide or aluminum oxide.

The semiconductor device 80 is provided on the nitride semiconductor device 40. The semiconductor device 80 of the present embodiment is, for example, a vertical trench type silicon (Si) metal oxide semiconductor field effect transistor (MOSFET).

The second silicon substrate 48 is provided on the sixth surface 2b. The second silicon substrate 48 has the seventh surface 48a and an eighth surface 48b facing the seventh surface 48a. The seventh surface 48a is in direct contact with the sixth surface 2b so as to be bonded to the sixth surface 2b. For example, the seventh surface 48a and the sixth surface 2b are sputter-etched by irradiating the seventh surface 48a and the sixth surface 2b with an inert gas ion beam, such as an argon gas ion beam, or an inert gas high-speed atomic beam, such as an argon atom, in a vacuum at room temperature (normal temperature). Then, the seventh surface 48a and the sixth surface 2b are bonded to each other. In addition, the method of bonding the seventh surface 48a and the sixth surface 2b to each other is not limited to the method described above.

For example, in the semiconductor device 100 of the present embodiment, the nitride semiconductor device 40 formed on the first silicon substrate 2 and the semiconductor device 80 formed on the second silicon substrate 48 are bonded to each other by the method described above.

The fact that the seventh surface 48a and the sixth surface 2b are bonded to each other can be clarified, for example, by observing the seventh surface 48a and the sixth surface 2b using a scanning electron microscope (SEM) or a transmission electron microscope (TEM).

In addition, it is preferable that at least one of the thickness of the first silicon substrate 2 and the thickness of the second silicon substrate 48 is 100 μm or less. In addition, it is preferable that both the thickness of the first silicon substrate 2 and the thickness of the second silicon substrate 48 are 100 μm or less. Then, in order to reduce the thickness of the first silicon substrate 2 or the thickness of the second silicon substrate 48 to 100 μm or less, it is preferable that the first silicon substrate 2 or the second silicon substrate 48 is made thin by polishing.

Here, an X axis, a Y axis perpendicular to the X axis, and a Z axis perpendicular to the X axis and the Y axis are defined. The first surface 8a, the second surface 8b, the third surface 6a, the fourth surface 6b, the fifth surface 2a, the sixth surface 2b, the seventh surface 48a, and the eighth surface 48b are provided perpendicular to the Z axis.

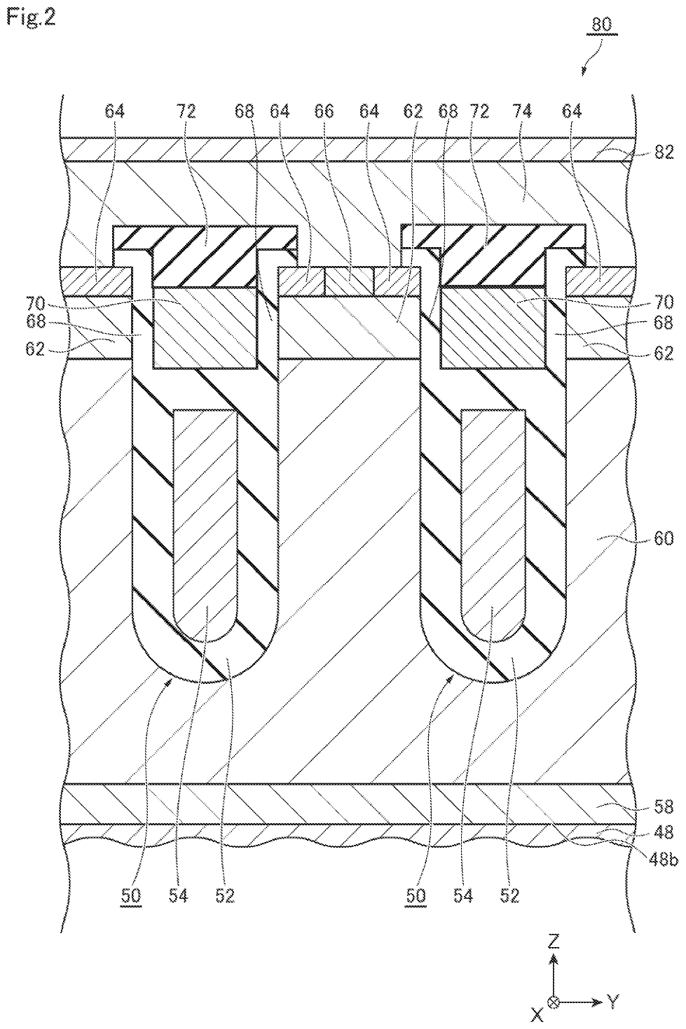

FIG. 2 is a schematic cross-sectional view of a main part of the semiconductor device 80 of the present embodiment.

A drain layer (an example of a first semiconductor layer) 58 is provided on the eighth surface 48b of the second silicon substrate 48, for example. However, for example, the drain layer 58 may be formed in the second silicon substrate 48, and is not particularly limited. The drain layer 58 is a layer that functions as a drain of the semiconductor device 80. The drain layer 58 is, for example, n⁺-type silicon (Si).

The first source electrode of the nitride semiconductor device 40 and the drain of the semiconductor device 80 are electrically connected to each other by the first source electrode 10, the first through electrode 30, the first silicon substrate 2, the second silicon substrate 48, and the drain layer 58. In addition, for example, the first source electrode of the nitride semiconductor device 40 and the drain of the semiconductor device 80 may be electrically connected to each other by using an external wiring line (not shown) instead of using the first through electrode 30.

A drift layer (an example of a second semiconductor layer) 60 is provided on the drain layer 58. The drift layer 60 is a layer that functions as a drift layer of the MOSFET. The drift layer 60 is, for example, an n⁻-type Si. The n-type impurity concentration in the drift layer 60 is lower than the n-type impurity concentration in the drain layer 58.

A base region (an example of the first semiconductor region) 62 is provided on the drift layer 60. The base region 62 is a region that functions as a base of the MOSFET. The base region 62 is a region that forms a channel when a voltage is applied to a second gate electrode 70, which will be described later, so that carriers can flow between a source region 64, which will be described later, and the drain layer 58. The base region 62 is, for example, p-type Si.

The source region (an example of a second semiconductor region) 64 is provided on the base region 62. The source region 64 is a region that functions as a source of the MOSFET. When an appropriate voltage is applied to the second gate electrode 70, carriers flow between the source region 64 and the drain layer 58. The source region 64 is, for example, n⁺-type Si. The n-type impurity concentration in the source region 64 is higher than the n-type impurity concentration in the drift layer 60.

A contact region 66 is provided on the base region 62 and is electrically connected to the base region 62 and the source region 64. The contact region 66 is provided to improve the electrical contact between the base region 62 and the source region 64 and a second source electrode 74, which will be described later. The contact region 66 is, for example, p⁺-type Si. The p-type impurity concentration in the contact region 66 is higher than the p-type impurity concentration in the base region 62.

A trench 50 is provided so as to reach the drift layer 60 from above the source region 64.

A field plate insulating film 52 is provided in the trench 50. For example, the field plate insulating film 52 is provided so as to cover a field plate electrode 54 described later. The field plate insulating film 52 insulates the field plate electrode 54 from the drift layer 60. For example, the field plate insulating film 52 contains silicon oxide (SiOx).

A gate insulating film 68 is provided on the field plate insulating film 52 in the trench 50. In addition, the gate insulating film 68 is provided between the second gate electrode 70 and the base region 62. The gate insulating film 68 functions as a gate insulating film of the MOSFET. The gate insulating film 68 is, for example, silicon oxide (SiOx).

The second gate electrode 70 is provided above the field plate insulating film 52 in the trench 50 so as to face a part of the drift layer 60, the base region 62, and the source region 64 with the gate insulating film 68 interposed between the second gate electrode 70 and each of the part of the drift layer 60, the base region 62, and the source region 64. The second gate electrode 70 is provided in the trench 50, which reaches the drift layer 60 from the source region 64, so as to face the base region 62 with the gate insulating film 68 interposed between the second gate electrode 70 and the base region 62. The second gate electrode 70 functions as a gate electrode of the MOSFET. The second gate electrode 70 contains, for example, a conductive material such as polysilicon containing impurities.

The field plate electrode 54 is provided in the trench 50 so as to face the drift layer 60 with the field plate insulating film 52 interposed between the field plate electrode 54 and the drift layer 60. For example, the field plate electrode 54 is provided side by side with the drift layer 60. The field plate electrode 54 reduces the electric field distribution in the drift layer 60. The field plate electrode 54 is, for example, a conductive material such as polysilicon containing impurities.

An interlayer insulating film 72 is provided on the gate insulating film 68 and the second gate electrode 70. The interlayer insulating film 72 contains, for example, silicon oxide (SiOx).

The second source electrode 74 is provided on the source region 64, the interlayer insulating film 72, and the contact region 66. The second source electrode 74 is electrically connected to the source region 64 and the contact region 66. The second source electrode 74 contains an electrically conductive material such as metal.

A source pad 82 is provided on the second source electrode 74 and is electrically connected to the second source electrode 74. The source pad 82 contains an electrically conductive material such as metal.

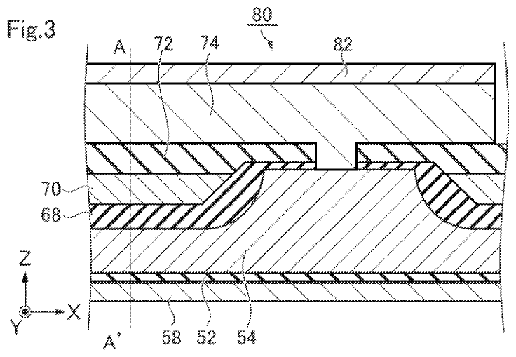

FIG. 3 is a schematic cross-sectional view of the semiconductor device 80 of the present embodiment. FIG. 3 is a schematic cross-sectional view of the semiconductor device 80 of the present embodiment in a plane parallel to the XZ plane. The schematic cross-sectional view shown in FIG. 2 corresponds to the schematic cross-sectional view in the A-A′ cross section of FIG. 3. The field plate electrode 54 has a portion extending in the Z direction on a side in the X direction with respect to the A-A′ cross section. Then, the first field plate electrode 54 is electrically connected to the second source electrode 74 by using the portion extending upward. In addition, the form of electrical connection between the field plate electrode 54 and the second source electrode 74 is not limited to this.

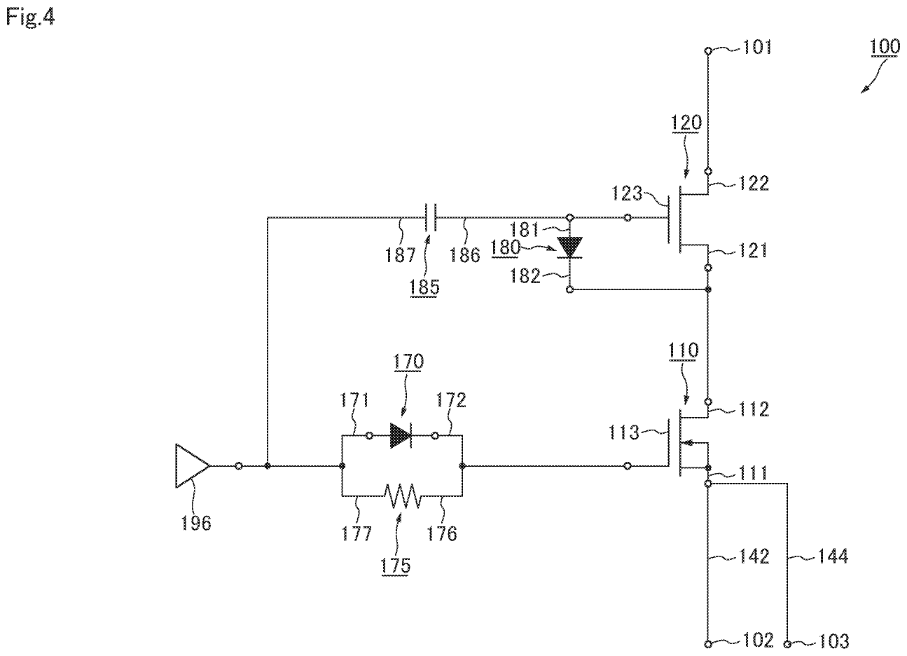

FIG. 4 is an example of an electric circuit diagram configured by the semiconductor device 100 of the present embodiment. FIG. 4 shows an electric circuit in which a drain electrode 112 of a normally-off transistor 110 and a source electrode 121 of a normally-on transistor 120 are cascode-connected to each other. A normally-off operation is realized by electrically connecting the normally-off transistor 110 and the normally-on transistor 120 in series to each other. For example, the nitride semiconductor device 40 is used as the normally-on transistor 120. In addition, for example, the semiconductor device 80 is used as the normally-off transistor 110.

The normally-off transistor 110 has a source electrode 111, a drain electrode 112, and a gate electrode 113. The normally-off transistor 110 corresponds to the semiconductor device 80. The breakdown voltage of the normally-off transistor 110 is, for example, 10 V or more and 30 V or less.

A wiring line 142 is connected to the source electrode 111. The wiring line 142 is connected to a source terminal 102. The source terminal 102 corresponds to, for example, the source pad 82.

In addition, a wiring line 144 is connected to the source electrode 111. The wiring line 144 is connected to a terminal 103. The terminal 103 is a terminal provided for Kelvin connection so that the gate drive current and the main circuit current, which flows between the drains and the sources of the normally-off transistor 110 and the normally-on transistor 120 do not share the source inductance.

The normally-on transistor 120 has a source electrode 121, a drain electrode 122, and a gate electrode 123. The normally-on transistor 120 corresponds to the nitride semiconductor device 40. The breakdown voltage of the normally-on transistor 120 is, for example, 600 V or more and 1200 V or less.

A capacitor 185 has a first end 186 and a second end 187. The first end 186 is electrically connected to the gate electrode 123.

A diode 180 (an example of a first diode) has an anode 181 (an example of a first anode) and a cathode 182 (an example of a first cathode). The anode 181 is electrically connected to the first end 186 and the gate electrode 123. The cathode 182 is electrically connected to the source electrode 121.

A resistor 175 has an end 176 (an example of a third end) and an end 177 (an example of a fourth end). The end 176 is electrically connected to the gate electrode 113.

A diode 170 (an example of a second diode) has an anode 171 (an example of a second anode) and a cathode 172 (an example of a second cathode). The anode 171 is electrically connected to the end 177. The cathode 172 is electrically connected to the gate electrode 113 and the end 176. The diode 170 is provided electrically in parallel with the resistor 175.

A gate drive circuit 196 is electrically connected to the second end 187, the end 177 and the anode 171. The gate drive circuit 196 outputs a signal for driving the normally-off transistor 110 and the normally-on transistor 120.

The operation of the electric circuit shown in FIG. 4 is described, for example, in JP 6392458 B2.

Next, the function and effect of the semiconductor device 100 of the present embodiment will be described.

In general, many HEMTs using nitride semiconductor materials are normally-on transistors. Here, in order to make the HEMT a normally-off transistor, it is conceivable to perform processing (mesa processing) such as forming a trench in the first nitride semiconductor layer 8 or the second nitride semiconductor layer 6. However, there is a problem that damage due to processing, such as etching damage, remains in the processed portion of the first nitride semiconductor layer 8 or the second nitride semiconductor layer 6. In addition, there is a problem that a leakage current increases or the reliability decreases due to the portion where the damage remains.

In addition, a junction-field effect transistor (JFET) type structure in which a p-type nitride semiconductor layer is inserted between the first gate electrode 14 and the first nitride semiconductor layer 8 can be considered. This JFET type structure realizes a normally-off operation by injecting holes from the p-type nitride semiconductor layer to suppress the generation of 2DEG below the p-type nitride semiconductor layer. However, even in the JFET type structure, the p-type nitride semiconductor layer is etched in a mesa shape. For this reason, there is a problem that etching damage remains on the side surface of the p-type nitride semiconductor layer and accordingly, a surface leakage current increases or the reliability decreases. In addition, a method of selectively growing the p-type nitride semiconductor layer on the first nitride semiconductor layer 8 can also be considered, but there is a problem that crystal defects are present in the selectively grown p-type nitride semiconductor layer.

Therefore, the semiconductor device 100 of the present embodiment includes: the first nitride semiconductor layer 8 having the first surface 8a and the second surface 8b facing the first surface 8a; the first source electrode 10 provided below the first surface 8a; the first drain electrode 12 provided below the first surface 8a; the first gate electrode 14 provided below the first surface 8a and the first gate electrode 14 being provided between the first source electrode 10 and the first drain electrode 12; the second nitride semiconductor layer 6 provided on the second surface 8b, the second nitride semiconductor layer 6 having the third surface 6a in contact with the second surface 8b and the fourth surface 6b facing the third surface 6a and the second nitride semiconductor layer 6 having a smaller band gap than the first nitride semiconductor layer 8; the first silicon substrate 2 provided on the fourth surface 6b and the first silicon substrate 2 having the fifth surface 2a in contact with the fourth surface 6b and the sixth surface 2b facing the fifth surface 2a; the second silicon substrate 48 provided on the sixth surface 2b and the second silicon substrate 48 having the seventh surface 48a bonded with the sixth surface 2b and the eighth surface 48b facing the seventh surface 48a; the drain layer (first semiconductor layer) 58 of first conductivity type provided on the second silicon substrate 48 or in the second silicon substrate 48; the drift layer (second semiconductor layer) 60 of first conductivity type provided on the drain layer 58 and the drift layer 60 having a lower concentration of impurities of first conductivity type than the drain layer 58; the base region (first semiconductor region) 62 of second conductivity type provided on the drift layer 60; the source region (second semiconductor region) 64 of first conductivity type provided on the base region 62; the second gate electrode 70 provided above the drain layer 58, the second gate electrode 70 facing the base region 62 with the gate insulating film 68 interposed between the second gate electrode 70 and the base region 62; and the second source electrode 74 provided on the source region 64 and the second source electrode 74 being electrically connected to the source region 64.

According to the semiconductor device 100, it is possible to obtain the normally-off semiconductor device 100 by combining a normally-on HEMT and the normally-off semiconductor device 80 so as to be cascode-connected to each other. For this reason, the above-described processing on the first nitride semiconductor layer 8, the second nitride semiconductor layer 6, or the p-type nitride semiconductor layer is not necessary. Therefore, it is possible to suppress an increase in leakage current and a decrease in reliability.

In addition, in the semiconductor device 100, the nitride semiconductor device 40 is formed on the first silicon substrate 2. Then, distortion that occurs due to the difference in distance between lattices due to the heterojunction between the first silicon substrate 2 and the other nitride semiconductor layer remains in the nitride semiconductor device 40 as an internal stress. This residual stress may become apparent due to a defect such as warpage of the nitride semiconductor device 40. However, such warpage is suppressed by the direct contact between the sixth surface 2b of the first silicon substrate 2 and the seventh surface 48a of the second silicon substrate 48.

In addition, by making the sixth surface 2b of the first silicon substrate 2 and the seventh surface 48a of the second silicon substrate 48 in direct contact with each other, the element area can be reduced as compared with a case where the nitride semiconductor device 40 and the semiconductor device 80 are disposed side by side on the plane.

In addition, when the nitride semiconductor device 40 and the semiconductor device 80 are disposed side by side on the plane, electrical connection between the nitride semiconductor device 40 and the semiconductor device 80 by a metal wire or the like is required. In the semiconductor device 100, however, since the sixth surface 2b of the first silicon substrate 2 and the seventh surface 48a of the second silicon substrate 48 are in direct contact with each other, it is possible to electrically connect the nitride semiconductor device 40 and the semiconductor device 80 to each other with low resistance.

When the nitride semiconductor device 40 and the semiconductor device 80 are used in combination, there is a possibility that the wiring resistance of the metal wire will increase, the number of assembly steps of the nitride semiconductor device 40 and the semiconductor device 80 will increase, and the size of the semiconductor device will increase. However, in the semiconductor device 100 of the present embodiment, an increase in wiring resistance is suppressed. In addition, since the above-described assembly step is performed by the contact between the first silicon substrate 2 and the second silicon substrate 48, this assembly step is a simple process. In addition, compared with the case where the nitride semiconductor device 40 and the semiconductor device 80 are arranged side by side on the plane, an increase in the size of the semiconductor device is also suppressed by the contact between the first silicon substrate 2 and the second silicon substrate 48.

In addition, since the sixth surface 2b and the seventh surface 48a are bonded to each other, it is possible to provide the semiconductor device 100 having a lower resistance.

When the thickness of the first silicon substrate or the second silicon substrate is 100 μm or less, the substrate thickness is small, so that it is possible to provide the semiconductor device 100 having a lower resistance.

When the second gate electrode 70 is provided in the trench 50 reaching the drift layer 60 from above the base region 62 so as to face the base region 62 with the field plate insulating film 52 interposed between the second gate electrode 70 and the base region 62, in other words, when the semiconductor device 80 is a vertical trench type MOSFET, the above-described internal stress is transferred to the bottom portion of the trench 50 through the first silicon substrate 2 and the second silicon substrate 48. As a result, the on-resistance of the semiconductor device 80 can be reduced, so that it is possible to provide the semiconductor device 100 having a lower resistance.

By providing the first through electrode 30 that penetrates the first nitride semiconductor layer 8 and the second nitride semiconductor layer 6 and electrically connects the first source electrode 10 and the second silicon substrate 48 to each other, the nitride semiconductor device 40 and the semiconductor device 80 can be connected to each other with lower resistance.

Therefore, it is possible to provide the semiconductor device 100 having a lower resistance.

According to the semiconductor device 100 of the present embodiment, it is possible to provide the semiconductor device 100 having a low resistance.

### Second Embodiment

A semiconductor device of the present embodiment is different from the semiconductor device of the first embodiment in that a second through electrode 34, which penetrates the first nitride semiconductor layer 8, the second nitride semiconductor layer 6, the first silicon substrate 2, and the second silicon substrate 48 and electrically connects the first gate electrode 14 and the field plate electrode 54 to each other, is further provided. Here, the description of the content overlapping the first embodiment will be omitted.

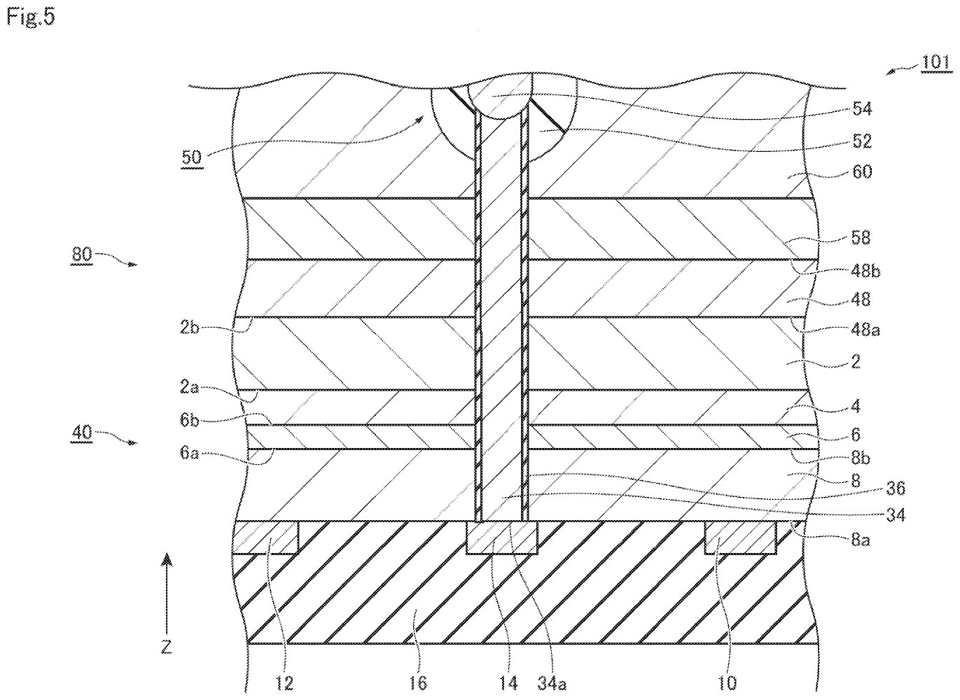

FIG. 5 is a schematic cross-sectional view of a semiconductor device 101 of the present embodiment. The second through electrode 34 penetrates the first nitride semiconductor layer 8, the second nitride semiconductor layer 6, the third nitride semiconductor layer 4, the first silicon substrate 2, the second silicon substrate 48, and the drain layer 58. One end 34a of the second through electrode 34 is electrically connected to the first gate electrode 14. The other end 34b of the second through electrode 34 is electrically connected to the field plate electrode 54. Here, as described above, the field plate electrode 54 is electrically connected to the second source electrode 74. Therefore, the first gate electrode 14 is electrically connected to the second source electrode 74 through the second via electrode 34 and the field plate electrode 54.

A second insulating film 36 is provided around the second through electrode 34. The second insulating film 36 insulates the first nitride semiconductor layer 8, the second nitride semiconductor layer 6, the third nitride semiconductor layer 4, the first silicon substrate 2, the second silicon substrate 48, the drain layer 58, the drift layer 60, the base region 62, and the source region 64 from the second through electrode 34, for example. The second insulating film 36 includes an insulating material, such as silicon oxide or aluminum oxide.

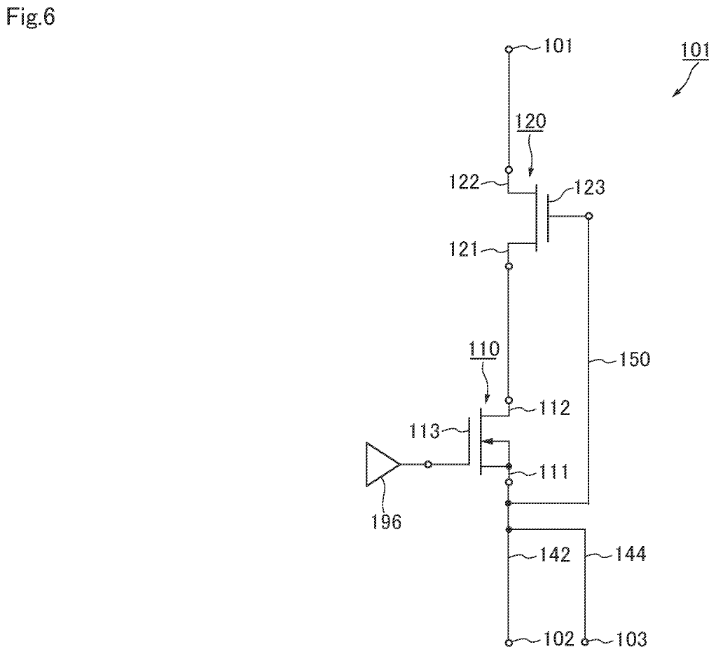

FIG. 6 is a circuit diagram of the semiconductor device 101 of the present embodiment. The gate drive circuit 196 is connected to the gate electrode 113 but not connected to the gate electrode 123. In addition, the source electrode 111 and the gate electrode 123 are connected to each other by a wiring line 150. The second through electrode 34 (FIG. 5) functions as the wiring line 150. FIG. 6 is another example of the electric circuit in which the source electrode 111 of the normally-off transistor 110 and the gate electrode 123 of the normally-on transistor 120 are cascode-connected to each other.

According to the semiconductor device 101 of the present embodiment as well, it is possible to provide the semiconductor device 101 having a low resistance.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first nitride semiconductor layer having a first surface and a second surface facing the first surface;
a first source electrode provided below the first surface;
a first drain electrode provided below the first surface;
a first gate electrode provided below the first surface and the first gate electrode being provided between the first source electrode and the first drain electrode;
a second nitride semiconductor layer provided on the second surface, the second nitride semiconductor layer having a third surface in contact with the second surface and a fourth surface facing the third surface and the second nitride semiconductor layer having a smaller band gap than the first nitride semiconductor layer;
a first silicon substrate provided on the fourth surface and the first silicon substrate having a fifth surface in contact with the fourth surface and a sixth surface facing the fifth surface;
a second silicon substrate provided on the sixth surface and the second silicon substrate having a seventh surface bonded with the sixth surface and an eighth surface facing the seventh surface;
a first semiconductor layer of first conductivity type provided on the second silicon substrate or in the second silicon substrate;
a second semiconductor layer of first conductivity type provided on the first semiconductor layer and the second semiconductor layer having a lower concentration of impurities of first conductivity type than the first semiconductor layer;
a first semiconductor region of second conductivity type provided on the second semiconductor layer;
a second semiconductor region of first conductivity type provided on the first semiconductor region;
a second gate electrode provided above the first semiconductor layer, the second gate electrode facing the first semiconductor region with a gate insulating film interposed between the second gate electrode and the first semiconductor region; and
a second source electrode provided on the second semiconductor region and the second source electrode being electrically connected to the second semiconductor region.

2. The semiconductor device according to claim 1,
wherein a thickness of the first silicon substrate or the second silicon substrate is 100 μm or less.

3. The semiconductor device according to claim 1,
wherein the second gate electrode is provided in a trench reaching the second semiconductor layer from the second semiconductor region, the second gate electrode facing the first semiconductor region with the gate insulating film interposed between the second gate electrode and the first semiconductor region.

4. The semiconductor device according to claim 1, further comprising:
a first through electrode penetrating the first nitride semiconductor layer and the second nitride semiconductor layer and the first through electrode electrically connecting the first source electrode and the second silicon substrate to each other.

5. The semiconductor device according to claim 3, further comprising:
a field plate electrode provided below the second gate electrode in the trench, the filed plate electrode facing the second semiconductor layer with a field plate insulating film interposed between the field plate electrode and the second semiconductor layer and the field plate electrode being electrically connected to the second source electrode; and
a second through electrode penetrating the first nitride semiconductor layer, the second nitride semiconductor layer, the first silicon substrate, and the second silicon substrate and the second through electrode electrically connecting the first gate electrode and the field plate electrode to each other.

6. The semiconductor device according to claim 1, further comprising:
a capacitor having a first end and a second end, the first end being electrically connected to the first gate electrode; and
a first diode having a first anode electrically connected to the first end and the first gate electrode and a first cathode electrically connected to the first source electrode.

7. The semiconductor device according to claim 6, further comprising:
a resistor having a third end electrically connected to the second gate electrode and a fourth end; and
a second diode having a second anode connected to the fourth end and a second cathode electrically connected to the second gate electrode and the third end.

8. The semiconductor device according to claim 1, further comprising:
a third nitride semiconductor layer provided between the second nitride semiconductor layer and the first silicon substrate,
wherein the fifth surface is in contact with the fourth surface via the third nitride semiconductor layer.
